(19) United States
(12) Patent Application Publication
(10) Pub. No.: US 2014/0120678 A1
(43) Pub. Date: May 1, 2014

(54) Methods for Selective and Conformal Epitaxy of Highly Doped Si-containing Materials for Three Dimensional Structures

(71) Applicants: Manabu Shinriki, Longmont, CO (US); Paul Brabant, E Greenbush, NY (US); Keith Chung, JR., Guilderland, NY (US)

(72) Inventors: Manabu Shinriki, Longmont, CO (US); Paul Brabant, E Greenbush, NY (US); Keith Chung, JR., Guilderland, NY (US)

(73) Assignee: MATHESON TRI-GAS, Basking Ridge, NJ (US)

(21) Appl. No.: 14/063,118

(22) Filed: Oct. 25, 2013

Related U.S. Application Data
(60) Provisional application No. 61/795,992, filed on Oct. 29, 2012.
(60) Provisional application No. 61/795,993, filed on Oct. 29, 2012.
(60) Provisional application No. 61/795,994, filed on Oct. 29, 2012.
(60) Provisional application No. 61/795,995, filed on Oct. 29, 2012.

(51) Int. Cl. H01L 29/66

(52) U.S. Cl. CPC H01L 29/66795
USPC 438/283

(57) ABSTRACT

The present invention addresses the key challenges in FinFET fabrication, that is, the fabrications of thin, uniform fins and also reducing the source/drain series resistance. More particularly, this application relates to FinFET fabrication techniques utilizing tetrasilane to enable conformal deposition with high doping using phosphate, arsenic and boron as dopants thereby creating thin fins having uniform thickness (uniformity across devices) as well as smooth, vertical sidewalls, while simultaneously reducing the parasitic series resistance.

### CROSS REFERENCE TO OTHER APPLICATIONS

This application claims benefit of priority to U.S. Provisional Application Nos. 61/795,992, 61/795,993, 61/795,994 and 61/795,995 all of which were filed on Oct. 29, 2012, the disclosures of which are fully incorporated herein by reference.

### BACKGROUND OF THE INVENTION

1. Field of the Invention

The present invention addresses the key challenges in the fabrication of three-dimensional structures, that is, the fabrications of thin, uniform fins and also reducing the source/drain series resistance. More particularly, this application relates to FinFET fabrication techniques utilizing tetrasilane to enable conformal deposition with high doping using phosphate, arsenic and boron as dopants thereby creating fins having uniform thickness (uniformity across devices) as well as smooth, vertical sidewalls, while simultaneously reducing the parasitic series resistance.

2. Description of the State of the Art

The relentless pursuit of scaling over the last 40 years, in accordance with the famed postulate known as Moore's Law, continues to be an aggressive goal. However, the time has come to rethink what is scalable and examine other ways of adding value to semiconductor devices. As scaling continued down to the 65 nm, 45 nm, etc. nodes, it became apparent that there was no viable options of continuing forth with the conventional (planar) MOSFET, resulting in the development of the double gate MOSFET (DG-FET) and triple gate MOSFET.

One type of DG-FETs is called a FinFET. Even though current conduction is in the plane of the wafer, it is not strictly a planar device. Rather, it is referred to as a quasi-planar device, because its geometry in the vertical direction (viz. the fin height) also affects device behavior. Because of the vertically thin channel structure, it is referred to as a fin because it resembles a fish's fin; hence the name FinFET. A gate can also be fabricated at the top of the fin, in which case it is a triple gate FET. Or optionally, the oxide above the fin can be made thick enough so that the gate above the fin is as good as not being present. This aids in reducing corner effects. In ultra thin triple gate FETs having a doped fin, the corners of the fin get inverted before the sidewalls of the fin get inverted. This is because the corners are under the influence of 2 gates (the top gate and one of the sidewall gates). This also makes the corners turn off later, as the gate voltage is ramped down. As a result, there is increased subthreshold leakage at the corners. There have been many efforts to study these corner effects and see how they can be minimized. It is believed that corner effects could be minimized if double gate FinFETs were used wherein the gate oxide over the fin is very thick.

Ultra thin fins result in better short channel effect (SCE), but increased series resistance. So a fine balance has to be achieved between the two goals. Also, the fabrication process has to be easily integrate-able into conventional CMOS process to the extent possible. Amongst the DG-FET types, the FinFET is the easiest one to fabricate; however, the fabrication of the uniform, ultra thin fins is one of the key challenges in FinFET fabrication. Due to non-ideal anisotropic over etch, the fins can end up having a slightly trapezoidal 302 or triangular 601 shape, see FIGS. 3A and 6A, respectively. Concave and convex surfaces can also end up during typical fabrication processes.

Selective epitaxial deposition is often utilized to form epilayers of silicon-containing materials (e.g., Si, SiGe and SiC) into the junctions. Generally, selective epitaxial deposition permits growth of epilayers on silicon moats with no growth on dielectric areas. Selective epitaxy can be used within semiconductor devices, such as elevated source/drains, source/drain extensions, contact plugs or base layer deposition of bipolar devices.

Generally, a selective epitaxy process involves a deposition reaction and an etch reaction. The deposition and etch reactions occur simultaneously with relatively different reaction rates to an epitaxial layer and to a polycrystalline layer. During the deposition process, the epitaxial layer is formed on a monocrystalline surface while a polycrystalline layer is deposited on at least a second layer, such as an existing polycrystalline layer and/or an amorphous layer. However, the deposited polycrystalline layer is generally etched at a faster rate than the epitaxial layer. Therefore, by changing the concentration of an etchant gas, the net selective process results in deposition of epitaxy material and limited, or no, deposition of polycrystalline material. For example, a selective epitaxy process may result in the formation of an epilayer of silicon-containing material on a monocrystalline silicon surface while no deposition is left on the spacer.

Selective epitaxy deposition of silicon-containing materials has become a useful technique during formation of elevated source/drain and source/drain extension features, for example, during the formation of silicon-containing MOSFET (metal oxide semiconductor field effect transistor) devices. Source/drain extension features are manufactured by etching a silicon surface to make a recessed source/drain feature and subsequently filling the etched surface with a selectively grown epilayers, such as a silicon germanium (SiGe) material. Selective epitaxy permits near complete dopant activation with in situ doping, so that the post annealing process is optional. Therefore, junction depth can be defined accurately by silicon etching and selective epitaxy. On the other hand, the ultra shallow source/drain junction inevitably results in increased series resistance. Also, junction consumption during silicide formation increases the series resistance even further. In order to compensate for junction consumption, an elevated source/drain is epitaxially and selectively grown on the junction. Typically, the elevated source/drain layer is undoped silicon.

However, current selective epitaxy processes have some drawbacks. In order to maintain selectivity during present epitaxy processes, chemical concentrations of the precursors, as well as reaction temperatures must be regulated and adjusted throughout the deposition process. If not enough silicon precursor is administered, then the etching reaction may dominate and the overall process is slowed down. If not enough etchant precursor is administered, then the deposition reaction may dominate reducing the selectivity to form monocrystalline and polycrystalline materials across the substrate surface. Also, current selective epitaxy processes usually require a high reaction temperature, such as about 800° C., 1,000° C. or higher. Such high temperatures are not desirable during a fabrication process due to thermal budget considerations and possible uncontrolled nitridation reactions to the substrate surface.

The performance of semiconductors devices may be further enhanced by increasing circuit performance. The amount of current that flows through the channel of a metal oxide semiconductor (MOS) transistor is directly proportional to a mobility of carriers in the channel, and the use of high mobility MOS transistors enables more current to flow and consequently faster circuit performance. For example, mobility of the carriers in the channel of a MOS transistor can be increased by producing a mechanical stress, i.e., strain, in the channel.

A number of approaches for inducing strain in Si— and Ge— containing materials have focused on exploiting the differences in the lattice constants between various crystalline materials. In one approach, thin layers of a particular crystalline material are deposited onto a different crystalline material in such a way that the deposited layer adopts the lattice constant of the underlying single crystal material.

Strain may also be introduced into single crystalline Si-containing materials by replacing Si in the lattice structure with a dopant, commonly referred to as substitutional doping. For example, substitution of germanium atoms for some of the silicon atoms in the lattice structure of single crystalline silicon produces a compressive strain in the resulting substitutionally doped single crystalline silicon material because the germanium atoms are larger than the silicon atoms that they replace. Alternatively, a tensile strain may be introduced into single crystalline silicon by substitutional doping with carbon, because carbon atoms are smaller than the silicon atoms that they replace. See, e.g., Judy L. Hoyt, “Substitutional Carbon Incorporation and Electronic Characterization of Si_{1-y}C_{y}/Si and Si_{1-x-y}GeₓC_{y}/Si Heterojunctions,” Chapter 3 in “Silicon-Germanium Carbon Alloy,” Taylor and Francis, N.Y., pp. 59-89, 2002, the disclosure of which is incorporated herein by reference.

In situ doping is often preferred over ex situ doping followed by annealing to incorporate the dopant into the lattice structure because the annealing may undesirably consume thermal budget. However, in practice in situ substitutional carbon doping is complicated by the tendency for the dopant to incorporate non-substitutionally during deposition, e.g., interstitially in domains or clusters within the silicon, rather than by substituting for silicon atoms in the lattice structure. See, e.g., the aforementioned article by Hoyt. Non-substitutional doping also complicates substitutional doping using other material systems, e.g., carbon doping of SiGe, doping of Si and SiGe with electrically active dopants, etc. As illustrated in FIG. 3.10 at page 73 of the aforementioned article by Hoyt, prior deposition methods have been used to make crystalline silicon having an in situ doped substitutional carbon content of up to 2.3 atomic %, which corresponds to a lattice spacing of over 5.4 Å and a tensile stress of less than 1.0 GPa. However, prior deposition methods are not known to have been successful for depositing single crystal silicon having an in situ doped substitutional carbon content of greater than 2.3 atomic %.

Therefore, there is a need to have a fabrication process to create thin fins with uniform thickness (uniformity across devices) as well as smooth, vertical sidewalls while being capable of selectively and epitaxially depositing silicon and silicon-containing materials while accomplishing in situ substitutional doping of Si-containing materials. Also, the parasitic series resistance needs to be brought down to acceptable levels. Desirably, such improved methods would be capable of achieving commercially significant levels of the above-mentioned outcomes without unduly sacrificing deposition speed, selectivity, and/or the quality (e.g., crystal quality) of the deposited materials. Furthermore, the process should be versatile to form silicon-containing materials with varied elemental concentrations while having a fast deposition rate and maintaining a process temperature in the range of about 250° C.-600° C., and preferably about 500° C. -550° C. while maintaining a pressure of less than 200 Torr.

### SUMMARY OF THE INVENTION

Deposition and/or growth methods have now been developed for the fabrication of FinFET devices that utilize a silicon source, such as, higher order silanes including straight and isomeric forms, such as, but not limited to tetrasilane (n-tetrasilane, iso-tetrasilane and cyclo-tetrasilane). The Si epitaxial layer is required to provide conformal deposition thickness and conformal doping profile with excellent crystal quality on different surface orientations (i.e., Si (100) vs Si (110) due to device performance design. To enhance the junction between the channel and source drain and/or between the source drain and contact (silicide formation), Fin structure to be thick by doped Si epitaxial process.

Another fabrication technique provides a method for minimizing the defect levels on all exposed Si crystallographic planes and thereby obtaining equivalent growth on all exposed planes. This is accomplished be by tailoring the cyclical deposition/etching (CDE) net growth rate.

Additionally, uniform Fin merge is described wherein at certain intervals of the fabrication process the Fins are etched back by selectively targeting the top of the epi growth to keep them open so a bottom up fill can occur. This etch back is a different etch chemistry than that used for etchant in the standard CDE process. The etch used for this purpose is HCl and it is used at high pressure. The combination of high HCl partial pressures and high total pressure in the CVD “viscous flow” regime allows for selectively etching the top of the Fin 110 growth vs the bottom of the Fin 110 growth.

Another embodiment discloses an in-situ doping (P, As, B) technique by using Si epitaxial process, required for conformal doping concentration on different orientations to keep resistivity similar. A highly doped Si epitaxial process (SiP, SiAs: 1E+20-5E+21 atoms/cm³) is able to alternate current ion implantation because ion implantation has problem of conformal dopant concentration by shadowing from FIN structure.

Ge incorporation (20-30%) into Si epitaxial process such as SiGeP, SiGeAs, SiGeB with higher order silanes, such as tetrasilane is helping crystallinity improvement on (110) orientation.

The foregoing paragraphs have been provided by way of general introduction, and are not intended to limit the scope of the following claims. The presently preferred embodiments, together with further advantages, will be best understood by reference to the following detailed description taken in conjunction with the accompanying drawings.

### BRIEF DESCRIPTION OF THE DRAWINGS

The accompanying drawings, which are incorporated in and form a part of the specifications, illustrate the preferred embodiments of the present invention, and together with the description serve to explain the principles of the invention.

In the Drawings:

FIG. 1 is a schematic view of a reactor set up for a system employing tetrasilane, a carbon source, an etchant gas, and a carrier gas for selectively depositing silicon-containing films in accordance with an embodiment.

FIG. 2 is a flowchart of the process according to various embodiments of the present invention.

FIG. 3A is a schematic cross-sectional view of Fins fabricated using a standard fabrication process whereby slightly trapezoidal shapes form (saw-tooth morphology) during the SEG process creating voids at the bottom of the Fins.

FIG. 3B is a schematic cross-sectional view of un-merged Fins fabricated with using a selected net growth and high pressure etch according to the present invention.

FIG. 3C is a schematic cross-sectional view of merged fins fabricated with using a selected net growth and high pressure etch according to the present invention.

FIG. 4 is two plots comparing the dopant profile for SiAs on Si (100) crystallographic plane to the dopant profile for Si (110) crystallographic plane under the same CDE conditions.

FIG. 5 is plot representing the dopant concentration in epitaxial films achieved using tetrasilane CDE over 12 cycles with AsH₃.

FIG. 6A is a schematic cross-sectional view of fins fabricated using a standard fabrication process whereby slightly triangular shapes form during the CDE process pinching off the upper surface creating voids at the bottom of the fins.

FIG. 6B is a schematic cross-sectional view of un-merged fins fabricated with using a selected net growth and high pressure etch according to the present invention.

FIG. 6C is a schematic cross-sectional view of merged fins fabricated with using a selected net growth and high pressure etch according to the present invention.

FIG. 7A is a schematic cross-sectional view of fins fabricated using a standard fabrication process whereby defects form on the Si(110) sidewall during the CDE process.

FIG. 7B is a schematic cross-sectional view of defect free fins on surfaces Si (100) and Si (110) fabricated using one step growth of SiGeP according to the present invention.

FIG. 7C is a schematic cross-sectional view of defect free fins on surfaces Si (100) and Si (110) fabricated using one step growth of SiGeAs according to the present invention.

### DETAILED DESCRIPTION OF THE PRESENT INVENTION

The present invention addresses the limitations described previously. The present invention provides a process for selectively and epitaxially depositing silicon and silicon-containing materials while accomplishing in situ substitutional doping of Si-containing materials. In addition, such improved methods disclosed herein are capable of achieving commercially significant levels of substitutional doping without unduly sacrificing deposition and/or growth speed, selectivity, and/or the quality (e.g., crystal quality) of the deposited materials. Furthermore, the process is versatile enough to form silicon-containing materials with varied elemental concentrations while having a fast deposition and/or growth rate and maintaining a process temperature in the range of about 250° C.-600° C., and preferably about 500° C.-550° C. while maintaining a pressure in the range of about 10 mTorr-200 Torr and preferably 10 mTorr-50 Torr and more preferably 10 mTorr-10 Torr. Finally, in the event the process requires multiple cycles as a result of etching there is no need to vary the temperature, that is, the etching step takes place at the same temperature as the deposition and/or growth step.

There are a number of deposition and/or growth parameters, as discussed in detail below, that are critical to selectively and epitaxially depositing silicon and silicon-containing materials while accomplishing in situ substitutional doping of Si-containing materials. It has been discovered that two critical parameters that allow one to accomplish the teachings of the present invention are the use higher order silanes including straight and isomeric forms, such as, but not limited to tetrasilane (n-tetrasilane, iso-tetrasilane and cyclo-tetrasilane) in combination with a low pressure chemical vapor deposition and/or growth system which has been modified in accordance with the present invention to incorporate the use of a high speed pump.

The use of higher order silanes, such as, but not limited to tetrasilane, enables higher deposition and/or growth rate at lower temperature and for silicon-containing films incorporating carbon, higher incorporation of substitutional carbon atoms than the use of mono-silane as a silicon source gas. Higher silanes, such as tetrasilane, while easier to deposit at lower temperatures, thereby providing greater selectivity by enabling amorphous growth versus poly crystalline material. Higher silanes have traditionally been difficult to employ in epitaxy processes as they are prone to polymerization, thus forming higher chain polymers (gas phase nucleation) which deposit in the form of particles. These particles cause defects in the Si material and can disrupt epitaxy, resulting in possible transition to amorphous or polysilicon layers depending on the temperature. Lowering the deposition and/or growth temperature reduces the potential for gas phase nucleation. Unfortunately, however, as the deposition and/or growth temperature is lowered the partial pressure of oxygen, an impurity present in the epitaxy process, increases resulting in the interstitial incorporation of oxygen into the Si material. By extrapolating the work of Lander, et al., JAP, v33(6): 2089-2092 (1962) at a deposition and/or growth temperature of 550° C. the partial pressure where oxygen is no longer stable on a clean surface is 10⁻¹⁶ Torr. Deposition and/or growth methods have now been developed for higher silanes, such as tetrasilane, that are much less sensitive to gas phase nucleation phenomena and that are useful for making a variety of substitutionally doped single crystalline Si-containing materials.

It has been found that epitaxial silicon films may be formed by exposing a substrate contained within a chamber to a relatively high carrier gas flow rate in combination with a relatively low flow rate of the silicon source such as but not limited to tetrasilane by utilizing a reduced pressure CVD system having a high speed pump, at a temperature of less than about 600° C. and a pressure in the range of about 10 mTorr-200 Torr, preferably 10 mTorr-50 Torr and more preferably 10 mTorr-10 Torr. The high speed pump is capable of flowing a carrier gas into said chamber at concentrations so high that any contaminants, such as but not limited to oxygen, water, carbon monoxide, carbon dioxide, siloxanes, disiloxanes, and higher siloxanes present are diluted out.

As semiconductor devices have scaled down to the 14 nm-node size the device structure has evolved to three-dimensional structure (i.e., FIN structure—Si FIN, SiGe FIN, III-V FIN), Si epitaxial layer is required to more conformal deposition thickness with excellent crystal quality on different surface orientation (i.e., Si (100) vs Si (110) due to device performance design. To fabricate a more ideal junction between channel and source/drain (S/D) and/or between source/drain and contact (Silicide formation), FIN structure to be thick by doped Si epitaxial process. Also, in order to keep resistivity similar, in-situ doping (P, As, B) techniques by using an Si epitaxial process is required to achieve conformal doping concentrations on different orientations. A highly doped Si epitaxial process (SiP, SiAs: 1E+20-5E+21 atoms/cm³) has the ability to alternate current ion implantation because ion implantation has problem of conformal dopant concentration by shadowing from FIN structure. Higher silanes, such as tetrasilane, while easier to deposit at lower pressure and temperature, enable conformal deposition with high doping (P, As, B) with optimal deposition, etching condition, deposition/etching cycle condition.

Ge incorporation (20-30%) into Si epitaxial process such as SiGeP, SiGeAs, SiGeB with higher silanes, such as tetrasilane aids crystallinity improvement on Si(110) orientation.

Furthermore, the crystalline Si may be in situ doped to contain relatively high levels of substitutional carbon by carrying out the deposition and/or growth at a relatively high flow rate using tetrasilane as a silicon source and a carbon-containing gas as a carbon source under these modified CVD conditions. The deposition and/or growth of a single crystalline silicon film onto the substrate takes place at a temperature of less than about 600° C. and a pressure in the range of about 10 mTorr-200 Torr, preferably 10 mTorr-50 Torr and more preferably 10 mTorr-10 Torr, the single crystalline silicon film comprises about 1.8 atomic % to about 3.0 atomic % substitutional carbon, as determined by x-ray diffraction. The deposition and/or growth of carbon-doped layers in accordance with this invention can be conducted with or without an etchant gas, selectively or non-selectively, as described in greater detail below. In the event an etchant gas is employed there is the added benefit that the pressure and temperature do not need to be cycled depending upon whether the cycle is a deposition and/or growth or etching cycle.

As discussed above, various deposition and/or growth parameters have been found to affect the incorporation of substitutional carbon into Si-containing films, including: the ratio of tetrasilane to other silicon sources the ratio of carbon source flow rate to tetrasilane flow rate; the carrier gas flow rate; the deposition and/or growth pressure; and the deposition and/or growth temperature. It has been found that certain combinations of these parameters are particularly advantageous for achieving relatively high levels of substitutional carbon incorporation into Si-containing films. In particular, the following combinations are preferred: a relatively high carrier gas flow rate (e.g., a relatively low ratio of tetrasilane flow rate to hydrogen carrier gas flow rate) in combination with at least one of the following: a relatively low tetrasilane flow rate (e.g., about 50 mg/min to about 200 mg/min) a relatively low deposition and/or growth pressure (e.g., preferably in the range of from about 10 millitorr to about ten Torr and more preferably at a pressure of less than 1 Torr; and a relatively low deposition and/or growth temperature (e.g., preferably in the range of from about 250° C. to about 600° C., more preferably in the range of from about 500° C. to about 550° C.).

The term “Si-containing material” and similar terms are used herein to refer to a broad variety of silicon-containing materials including without limitation Si (including crystalline silicon), Si:C (e.g., carbon-doped crystalline Si), SiGe and SiGeC (e.g., carbon-doped crystalline SiGe). As used herein, “carbon-doped Si”, “Si:C”, “SiGe”, “carbon-doped SiGe”, “SiGe:C” and similar terms refer to materials that contain the indicated chemical elements in various proportions and, optionally, minor amounts of other elements. For example, “SiGe” is a material that comprises silicon, germanium and, optionally, other elements, e.g., dopants such as carbon and electrically active dopants. Thus, carbon-doped Si may be referred to herein as Si:C or vice versa. Terms such as “Si:C”, “SiGe”, and “SiGe:C” are not stoichiometric chemical formulas per se and thus are not limited to materials that contain particular ratios of the indicated elements. The percentage of a dopant (such as carbon, germanium or electrically active dopant) in a Si-containing film is expressed herein in atomic percent on a whole film basis, unless otherwise stated.

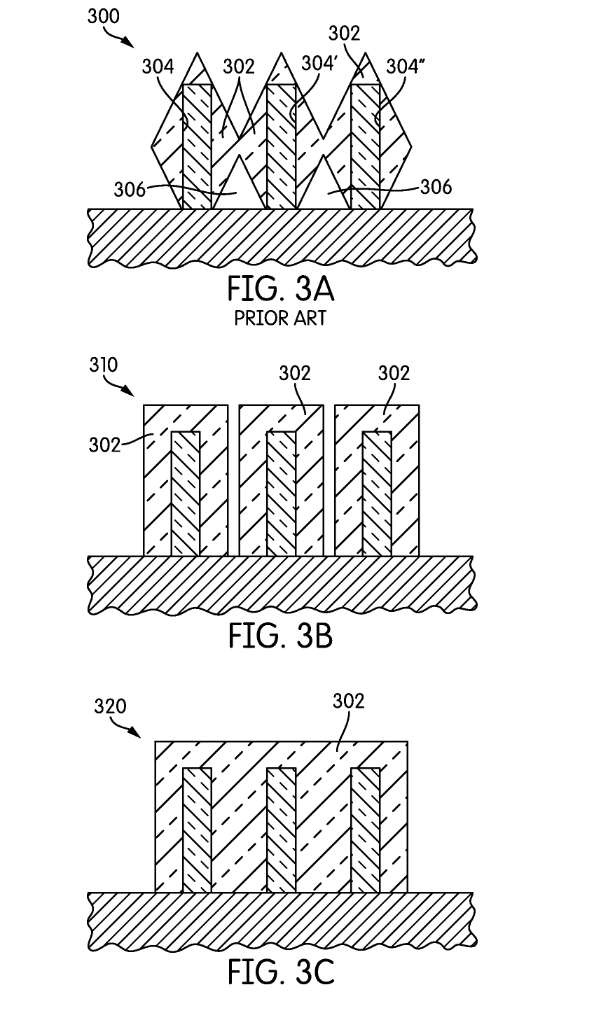

The amount of carbon substitutionally doped into a Si-containing material may be determined by measuring the perpendicular lattice spacing of the doped Si-containing material by x-ray diffraction. See, e.g., Judy L. Hoyt, “Substitutional Carbon Incorporation and Electronic Characterization of Si_{1-y}C_{y}/Si and Si_{1-x-y}GeₓC_{y}/Si Heterojunctions,” Chapter 3 in “Silicon-Germanium Carbon Alloy,” Taylor and Francis, N.Y., pp. 59-89, 2002. As illustrated in FIG. 3.10 at page 73 of the aforementioned article by Hoyt, the total carbon content in the doped silicon may be determined by SIMS, and the non-substitutional carbon content may be determined by subtracting the substitutional carbon content from the total carbon content. The amount of other elements substitutionally doped into other Si-containing materials may be determined in a similar manner.

Various embodiments provide methods for depositing carbon-, arsenic, phosphorous, boron doped Si-containing materials (such as carbon-doped single crystalline Si) using a silicon source that comprises tetrasilane, a carbon source and, source(s) of arsenic, phosphorous, boron elements such as electrical active dopant(s). Under the modified chemical vapor deposition and/or growth conditions taught herein and described in further detail below, the delivery of tetrasilane and a carbon source to the surface of a substrate preferably results in the formation of an epitaxial carbon-doped Si-containing film on the surface of the substrate. In certain selective deposition and/or growths an etchant gas may be delivered to the substrate in conjunction with tetrasilane and carbon source, arsenic, phosphorous, boron source and the Si containing film is deposited selectively over single crystal substrates or single crystal regions of mixed substrates. Methods employing relatively high deposition and/or growth rates are preferred, and in preferred embodiments such methods have been found to result in the deposition and/or growth of in situ doped crystalline Si-containing materials containing relatively high levels of substitutional carbon.

“Substrate,” as that term is used herein, refers either to the workpiece upon which deposition and/or growth is desired, or the surface exposed to the deposition and/or growth gas(es). For example, the substrate may be a single crystal silicon wafer, or may be a semiconductor-on-insulator (SOI) substrate, or may be an epitaxial Si, SiGe or III-V material deposited upon such wafers. Workpieces are not limited to wafers, but also include glass, plastic, or any other substrate employed in semiconductor processing. The term “mixed substrate” is known to those skilled in the art, see U.S. Pat. No. 6,900,115 which is hereby incorporated herein by reference in its entirety and particularly for the purpose of describing mixed substrates. As discussed in U.S. Pat. No. 6,900,115, a mixed substrate is a substrate that has two or more different types of surfaces. For example, a mixed substrate may comprise a first surface having a first surface morphology and a second surface having a second surface morphology. In certain embodiments, carbon-doped Si-containing layers are selectively formed over single crystal semiconductor materials while minimizing and more preferably avoiding deposition and/or growth over adjacent dielectrics. Examples of dielectric materials include silicon dioxide (including low dielectric constant forms such as carbon-doped and fluorine-doped oxides of silicon), silicon nitride, metal oxide and metal silicate. The terms “epitaxial”, “epitaxially” “heteroepitaxial”, “heteroepitaxially” and similar terms are used herein to refer to the deposition and/or growth of a crystalline Si-containing material onto a crystalline substrate in such a way that the deposited layer adopts or follows the lattice constant of the substrate. Epitaxial deposition and/or growth may be heteroepitaxial when the composition of the deposited layer is different from that of the substrate.

Even if the materials are made from the same element, the surfaces can be different if the morphologies (crystallinity) of the surfaces are different. The processes described herein are useful for depositing Si-containing films on a variety of substrates, but are particularly useful for mixed substrates having mixed surface morphologies. Such a mixed substrate comprises a first surface having a first surface morphology and a second surface having a second surface morphology. In this context, “surface morphology” refers to the crystalline structure of the substrate surface. Amorphous and crystalline are examples of different morphologies. Polycrystalline morphology is a crystalline structure that consists of a disorderly arrangement of orderly crystals and thus has an intermediate degree of order. The atoms in a polycrystalline material are ordered within each of the crystals, but the crystals themselves lack long range order with respect to one another. Single crystal morphology is a crystalline structure that has a high degree of long range order. Epitaxial films are characterized by a crystal structure and orientation that is identical to the substrate upon which they are grown, typically single crystal. The atoms in these materials are arranged in a lattice-like structure that persists over relatively long distances (on an atomic scale). Amorphous morphology is a non-crystalline structure having a low degree of order because the atoms lack a definite periodic arrangement. Other morphologies include microcrystalline and mixtures of amorphous and crystalline material. As used herein, “single-crystal” or “epitaxial” is used to describe a predominantly large crystal structure that may have a tolerable number of faults therein, as is commonly employed for transistor fabrication. The skilled artisan will appreciate that crystallinity of a layer generally falls along a continuum from amorphous to polycrystalline to single-crystal; the skilled artisan can readily determine when a crystal structure can be considered single-crystal or epitaxial, despite low density faults. Specific examples of mixed substrates include without limitation single crystal/polycrystalline, single crystal/amorphous, epitaxial/polycrystalline, epitaxial/amorphous, single crystal/dielectric, epitaxial/dielectric, conductor/dielectric, and semiconductor/dielectric. The term “mixed substrate” includes substrates having more than two different types of surfaces, and thus the skilled artisan will understand that methods described herein for depositing Si-containing films onto mixed substrates having two types of surfaces may also be applied to mixed substrates having three or more different types of surfaces.

Embodiments of the invention generally provide methods and apparatus for forming and treating a silicon-containing epitaxial layer. Specific embodiments pertain to methods and apparatus for forming and treating an epitaxial layer during the manufacture of a transistor.

As used herein, epitaxial deposition and/or growth refers to the deposition and/or growth of a single crystal layer on a substrate, so that the crystal structure of the deposited layer matches the crystal structure of the substrate. Thus, an epitaxial layer or film is a single crystal layer or film having a crystal structure that matches the crystal structure of the substrate. Epitaxial layers are distinguished from bulk substrates and polysilicon layers.

Throughout the application, the terms “silicon-containing” materials, compounds, films or layers should be construed to include a composition containing at least silicon and may contain germanium, carbon, boron, arsenic, phosphorus, gallium and/or aluminum. Other elements, such as metals, halogens or hydrogen may be incorporated within a silicon-containing material, compound, film or layer, usually in part per million (ppm) concentrations. Compounds or alloys of silicon-containing materials may be represented by an abbreviation, such as Si for silicon, SiGe for silicon germanium, Si:C for silicon carbon and SiGeC for silicon germanium carbon. The abbreviations do not represent chemical equations with stoichiometrical relationships, nor represent any particular reduction/oxidation state of the silicon-containing materials.

One or more embodiments of the invention generally provide processes to selectively and epitaxially deposit silicon-containing materials on monocrystalline surfaces of a substrate during fabrication of electronic devices. A substrate containing a monocrystalline surface (e.g., silicon or silicon germanium) and at least a secondary surface, such as an amorphous surface and/or a polycrystalline surface (e.g., oxide or nitride), is exposed to an epitaxial process to form an epitaxial layer on the monocrystalline surface while forming limited or no polycrystalline layer on the secondary surfaces. The epitaxial process typically includes repeating a cycle of a deposition and/or growth process and an etching process until the desired thickness of an epitaxial layer is grown. Exemplary alternating deposition and etch processes are disclosed in U.S. Pat. No. 7,312,128 the entire content of which is incorporated herein by reference.

In one or more embodiments, the deposition process includes exposing the substrate surface to a deposition gas containing at least a silicon source and a carrier gas, wherein the carrier has a flow rate from 0-20,000 and preferably from 2,000 to 10,000 and more preferably from 100 to 2000 times greater than the flow rate of the silicon source. The deposition gas may also include a germanium source and/or carbon source, as well as a dopant source. In particular embodiments, the deposition gas contains a sufficient amount of an n-type dopant precursor that results in the epitaxial film containing dopant in the range of 1E+20/cm³-5E+21/cm³ and preferably 5E+20/cm³-1E+21/cm³. Dopant concentration can be changed in a continuous epitaxial process in order to obtain desired device performance (for example, junction performance on interface between fin and source and drain and source and drain self, and contact resistance on interface between source drain and contact (silicide formation). In specific embodiments, the final epitaxial film contains at least about 2E+20/cm³ of an n-type dopant, and more specifically, at least about 5E+20/cm³-1E+21/cm³ of an n-type dopant. These results are extremely surprising in that dopant levels this high have not traditionally been achievable but are now achieved through the use of the processes disclosed in this invention. As used herein, these levels of dopant concentration will be referred to as heavily doped with an either an n-type or p-type dopant. Examples of suitable n-type dopants include, but not limited to, P, As, and Sb and suitable p-type dopant include, but are not limited to Ge and B. During the deposition process, an epitaxial layer is formed on the monocrystalline surface of the substrate, while a polycrystalline/amorphous layer is formed on secondary surfaces, such as dielectric, amorphous and/or polycrystalline surfaces, which will be collectively referred to as “secondary surfaces”. Subsequently, the substrate is exposed to an etching gas. Typically, the etching gas includes a carrier gas and an etchant, such as chlorine gas or hydrogen chloride. The etching gas removes silicon-containing materials deposited during the deposition process. During the etching process, the polycrystalline/amorphous layer is removed at a faster rate than the epitaxial layer. Therefore, the net result of the deposition and etching processes forms epitaxially grown silicon-containing material on monocrystalline surfaces while minimizing growth, if any, of polycrystalline/amorphous silicon-containing material on the secondary surfaces. A cycle of the deposition and etching processes may be repeated as needed to obtain the desired thickness of silicon-containing materials. The silicon-containing materials which can be deposited by embodiments of the invention include silicon, silicon germanium, silicon carbon, silicon germanium carbon, silicon-phosphorus, silicon-arsenic, silicon-boron, silicon-carbon phosphorous, silicon-carbon arsenic, silicon carbon boron, silicon-germanium phosphorous, silicon-germanium arsenic, silicon-germanium boron, and variants thereof, including dopants.

Depending on the structure of the FIN (height, pitch between Fin-Fin, merged FIN or un-merged FIN) desired depositing and etching will occur for 1-50 cycles. In general, deposition processes may be conducted at lower temperatures than etching reactions, since etchants often need a high temperature to be activated. However, tetrasilane, due to the fact it can be deposited amorphously, allows for the etching process to be maintained at temperatures consistent with the deposition temperature thereby minimizing the effort to regulated and adjusted the reaction temperatures throughout the deposition process. Undoped Si Fin is covered by conformal SiP, SiAs, etc with high doping (1E+20-5E+21, preferably greater than 5E+20 to make shallow junction in 1-10 nm with 1-10 cycle). Any doped films whether nFET, or pFET deposited on the 110 plane will have high defect levels. Undoped SiC films are also extremely defective on 110 plane. For example, if 50 Å is deposited and 25 Å is etched back for a net growth of 25 Å it is found there is a high level of defects on the 110 plane. By reducing the net growth to 5˜15 Å per cycle (preferable 10-15 Å) by reducing deposition thickness, defects are significantly reduced resulting in equivalent growth on all exposed planes. In addition, Ge and B for pFET or C and P/As for nFET, incorporates at nearly the same level with this technique.

Hydrogen is typically a preferred carrier gas due to improved hydrogen termination. However other inert carrier gases such as argon, helium, and nitrogen may also be employed.

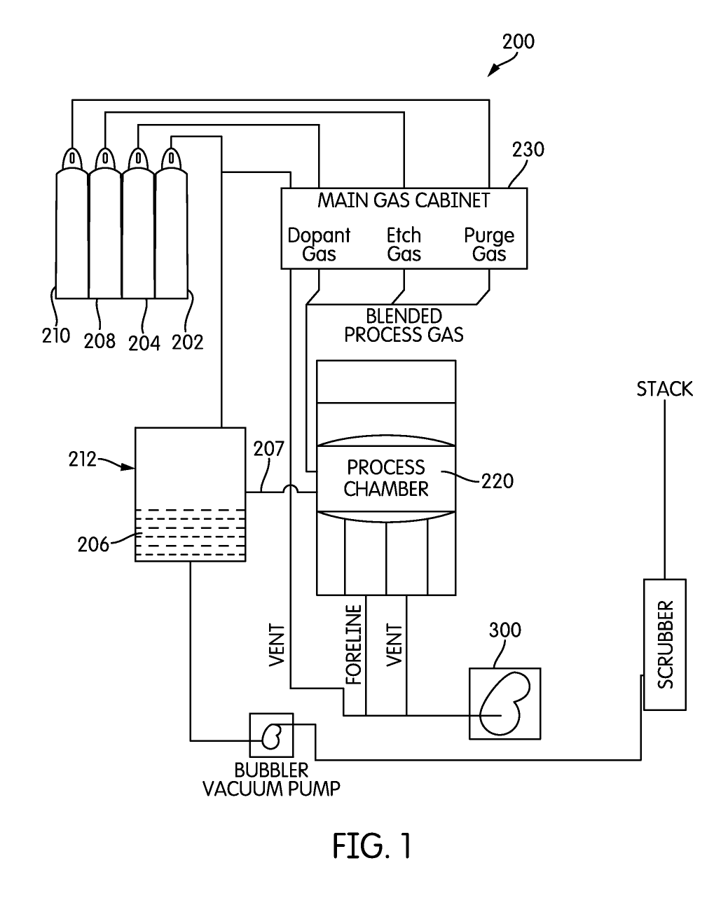

FIG. 1 illustrates a preferred reactor system 200 employing a carrier gas 202 (hydrogen in the illustrated embodiments), a carbon source 204 (methylsilane in the illustrated embodiment), a silicon source 206 (tetrasilane in the illustrated embodiment) and an etching gas (HCl) 208 and a purifier (not shown) located in the etchant line. Reactor system 200 utilized by the present invention comprises a Centura® RP-CVD (Reduced Pressure-Vacuum Chemical Vapor Deposition) manufactured by Applied Materials and modified according to the present invention by adding a high flow pump 300 as discussed further below.

The gases introduced into the reactor system 200 are highly purified by a gas purifier (not shown) before being introduced into reaction chamber 220. Therefore, it is necessary to provide the gas purifier such that the gas is introduced into the reaction chamber 220 after having been purified highly. Thereby, an impurity of oxygen, water, siloxanes, carbon monoxide (CO), carbon dioxide (CO₂) or the like included in the gas, is minimized. Some of the carrier gas 202 flow is shunted to a vaporizer in the form of a bubbler 212, from which carrier gas 202 carries vaporized tetrasilane 207 at a ratio of approximately 0.005, thereby forming a saturated process gas.

The carrier gas 202 merges with the other reactants at the main gas cabinet 230, upstream of the injection manifold (not shown) for deposition chamber 220. A source of etchant gas 208 is also optionally provided for selective deposition processes.

As illustrated, the reactor system 200 also includes a high speed pump 300. It has been discovered that this high speed pump 300 is essential to the present invention as it allows main carrier gas 202 flowing to the chamber to flow at a much higher rate than that of tetrasilane saturated vapor 207, that is in the range of 0-20,000 and preferably from 2,000 to 10,000 and more preferably from 100 to 2000 times greater than the flow rate of the tetrasilane saturated vapor 207. These high flow rates at the low deposition temperatures, that is, less than 550° C. which are disclosed herein, minimize the incorporation of oxygen containing impurities such as but not limited to oxygen, water, carbon monoxide, carbon dioxide, siloxanes, disiloxanes, higher siloxanes into the Si film. It is preferable that the interstitial oxygen content should be 1E+18 atom/cm³ or lower and preferably less than 2E+17 atom/cm³. Interfacial oxygen content should be below SIMS detectable limits (dose at interface) with a background of 5E+17 atom/cm³. Interstitial carbon content should be 5E+17 atom/cm³ or lower. Interfacial carbon should be below SIMS detectable limits with a minimum background of 5E+17 atom/cm³ or lower. This requirement is accomplished as a result of the high speed pump 300 as carrier gas 202 at pressures in the range of about 10 mTorr-200 Torr, preferably 10 mTorr-50 Torr and more preferably 10 mTorr-10 Torr has a flow rate of up to 50 slm which is approximately two hundred times that of tetrasilane saturated vapor 207; consequently, impurities that may be present in reaction chamber 220 are literally diluted out.

A central controller (not shown), electrically connected to the various controllable components of reactor system 200. The controller is programmed to provide gas flows, temperatures, pressures, etc., to practice the deposition processes as described herein upon a substrate housed within reaction chamber 220. As will be appreciated by the skilled artisan, the controller typically includes a memory and a microprocessor, and may be programmed by software, hardwired or a combination of the two, and the functionality of the controller may be distributed among processors located in different physical locations. Accordingly, the controller can also represent a plurality of controllers distributed through reactor system 200.

In the illustrated embodiment, with the carbon source 204 in combination with tetrasilane saturated vapor 207, selective deposition of high substitutional carbon content Si:C can be achieved, as disclosed hereinabove. In another embodiment, the dopant hydride source 210 is preferably also provided to produce in situ doped semiconductor layers with enhanced conductivity. Preferably, for Si:C epitaxy, the dopant hydride is arsine or phosphine, and the layer is n-type doped. More preferably, for selective deposition embodiments, the diluent inert gas for the dopant hydride is also hydrogen gas. Thus, phosphine 210 and methylsilane 204 are preferably stored at their source containers in, e.g., hydrogen. Typical dopant hydride concentrations are 0.1% to 10% in hydrogen 202, more typically 0.5% to 1.0% in hydrogen for arsine and phosphine. Typical carbon source concentrations are 5% to 50% in hydrogen 202, more typically 10% to 30% in hydrogen. For example, experiments are being conducted with 10% methylsilane 204 in hydrogen 202.

According to a first embodiment of the invention, blanket or nonselective epitaxy with alternating steps of deposition and etch results in improved crystallinity of epitaxial films grown using a higher order silane compared to continuous deposition. Cyclic deposition and etching is a general solution to obtain the best quality of epitaxial layer and conformal deposition. However, if the device allows for Ge incorporation, GeH₄ or alternatively Ge₂H₆ can utilized as an alternative technique for improvement to the crystallinity. As a result, when GeH₄ is used for process, relatively the net growth can be increased from 5-15 Å per cycle to 15 Å-30 Å, it makes throughput increase by reducing cycle number. As used herein, “higher order silane” refers to a tetrasilane including straight and isomeric forms, such as, but not limited to tetrasilane (n-tetrasilane, iso-tetrasilane and cyclo-tetrasilane), or higher silane precursor. An exemplary process includes loading a substrate into a process chamber and adjusting the conditions within the process chamber to a desired temperature and pressure. Then, a deposition process is initiated to form an epitaxial layer on a monocrystalline surface of the substrate at a rate of approximately 2-4 nm per minute. The deposition process is then terminated.

The substrates may be unpatterned or patterned. Patterned substrates are substrates that include electronic features formed into or onto the substrate surface. The patterned substrate usually contains monocrystalline surfaces and at least one secondary or feature surface that is non-monocrystalline, such as a dielectric, polycrystalline or amorphous surfaces. Monocrystalline surfaces include the bare crystalline substrate or a deposited single crystal layer usually made from a material such as silicon, silicon germanium or silicon carbon. Polycrystalline or amorphous surfaces may include dielectric materials, such as polysilicon, photoresist materials, oxides or nitrides, specifically silicon oxide or silicon nitride, as well as amorphous silicon surfaces or combinations thereof.

After loading a substrate into the process chamber, the conditions in the process chamber are adjusted to a predetermined temperature and pressure. The temperature is tailored to the particular conducted process. Generally, the process chamber is maintained at a temperature below about 550° C. during deposition and etching. The process chamber is usually maintained at a pressure in the range of about 10 mTorr-200 Torr, preferably 10 mTorr-50 Torr and more preferably 10 mTorr-10 Torr during deposition. The pressure may fluctuate during and between process steps, but is generally maintained constant.

During the deposition process the substrate is exposed to a deposition gas to form an epitaxial layer. The substrate is exposed to the deposition gas for a period of time of about 0.5 seconds to about 30 seconds, for example, from about 1 second to about 20 seconds, and more specifically from about 5 seconds to about 10 seconds. In a specific embodiment, the deposition step lasts for about 10 to 11 seconds. The specific exposure time of the deposition process is determined in relation to the exposure time during a subsequent etching process, as well as particular precursors and temperature used in the process. Generally, the substrate is exposed to the deposition gas long enough to form a maximized thickness of an epitaxial layer.

In one or more embodiments, the deposition gas contains at least a silicon source or precursor and a carrier gas, and may contain at least one secondary elemental source, such as a carbon source or precursor and/or a germanium source or precursor. Also, the deposition gas may further include a dopant compound to provide a source of a dopant, such as boron, arsenic, phosphorus, gallium and/or aluminum. In an alternative embodiment, the deposition gas may include at least one etchant.

The silicon sources as introduced to said chamber typically has a purity level in the range of approximately 95% to approximately 99.9% and having oxygenated impurities less than 2000 ppm and preferably having oxygenated impurities less than 2 ppm and more preferably having oxygenated impurities less than 500 ppb.

The silicon source is usually provided into the process chamber at a rate in a range from about 1 sccm to about 500 sccm, preferably from about 5 sccm to about 300 sccm, and more preferably from about 10 sccm to about 50 sccm, for example, about 25 sccm. In a specific embodiment, tetrasilane is flowed at about 20 sccm. Silicon sources useful in the deposition gas to deposit silicon-containing compounds include but are not limited to tetrasilane, halogenated tetrasilanes and organotetrasilanes. Halogenated silanes include compounds with the empirical formula X′_{y}Si₄H_{(10-y)}, where X′=F, Cl, Br or I. Organosilanes include compounds with the empirical formula R_{y}Si₄H_{(10-y)}, where R=methyl, ethyl, propyl or butyl. Organosilane compounds have been found to be advantageous silicon sources as well as carbon sources in embodiments which incorporate carbon in the deposited silicon-containing compound.

The silicon source is usually provided into the process chamber along with a process carrier gas. The process carrier gas has a flow rate from about 1 slm (standard liters per minute) to about 50 slm, at a pressure of less than 100 Torr. For example, from about 5 slm to about 45 slm, and more specifically from about 5 slm to about 10 slm, for example, about 10 slm at a pressure of about less than 100 Torr. Process carrier gases may include helium, nitrogen (N₂), hydrogen (H₂), argon, and combinations thereof. A process carrier gas may be selected based on the precursor(s) used and/or the process temperature during the epitaxial process. Usually the process carrier gas is the same throughout for each of the deposition and etching steps. However, some embodiments may use different process carrier gases in particular steps. Typically, hydrogen is utilized as a carrier gas in embodiments featuring low temperature (e.g., less than 550° C.) processes.

The deposition gas used also contains at least one secondary elemental source, such as a dopant source. A carbon source may be added during deposition to the process chamber with the silicon source and carrier gas to form a silicon-containing compound, such as a silicon carbon material. A carbon source, i.e. 100%, is usually provided into the process chamber at a rate in the range from about 0.1 sccm to about 100 sccm, for example, from about 5 sccm to about 70 sccm, and more specifically, from about 30 sccm to about 70 sccm, for example, about 50 sccm.

Carbon sources useful to deposit silicon-containing compounds include organosilanes, cyclohexasilanes, alkyls, alkenes and alkynes of ethyl, propyl and butyl. Such carbon sources include but are not limited to carbon sources having a general formula of SiₓH_{y}(CH₃)_{z}, where x is an integer in the range of 1 to 6 and where y and z are each independently an integer in the range of 0 to 6, methylated cyclohexasilane or dodecamethylcyclohexasilane (Si₆C₁₂H₃₆) and silylalkanes such as tetramethyldisilane (TMDS), monosilylmethane, disilylmethane, trisilylmethane and tetrasilylmethane, and/or alkylsilanes such as monomethyl silane (MMS), and dimethyl silane, methylsilane (CH₃SiH₃), dimethylsilane ((CH₃)₂SiH₂), ethylsilane (CH₃CH₂SiH₃), methane (CH₄), ethylene (C₂H₄), ethyne (C₂H₂), propane (C₃H₈), propene (C₃H₆), butyne (C₄H₆), as well as others. The carbon concentration of an epitaxial layer is in the range from about 1.8 atomic % to about 3 atomic %. Alternatively, a germanium source and a carbon source may both be added during deposition into the process chamber with the silicon source and carrier gas to form a silicon-containing compound, such as a silicon carbon or silicon germanium carbon material.

The carbon sources as introduced to said chamber typically has a purity level in the range of approximately 97% to approximately 99.9% and having oxygenated impurities less than 100 ppm and preferably having oxygenated impurities less than 10 ppm and more preferably having oxygenated impurities less than 500 ppb.

The deposition gas used during deposition may further include at least one dopant compound to provide a source of elemental dopant, such as boron, arsenic, phosphorus, gallium or aluminum. Dopants provide the deposited silicon-containing compounds with various conductive characteristics, such as directional electron flow in a controlled and desired pathway required by the electronic device. Films of the silicon-containing compounds are doped with particular dopants to achieve the desired conductive characteristic. In one example, the silicon-containing compound is doped n-type, such as with phosphorus, antimony and/or arsenic to a concentration in the range from about 10²⁰ atoms/cm³ to about 10²¹ atoms/cm³.

A dopant source is usually provided into the process chamber during deposition in the range from about 0.1 sccm to about 20 sccm, for example, from about 0.3 sccm to about 10 sccm, and more specifically from about 0.5 sccm to about 5 sccm, for example, about 3 sccm. Dopants may also include arsine (AsH₃), phosphine (PH₃) and alkylphosphines, such as with the empirical formula RₓPH₍₃₋ₓ₎, where R=methyl, ethyl, propyl or butyl and x=1, 2 or 3. Alkylphosphines include trimethylphosphine ((CH₃)₃P), dimethylphosphine ((CH₃)₂PH), triethylphosphine ((CH₃CH₂)₃P) and diethylphosphine ((CH₃CH₂)₂PH). Alkylarsines include trimethylarsine ((CH₃)₃As), dimethylarsine ((CH₃)₂AsH), triethylarsine ((CH₃CH₂)₃As) and diethylarsine ((CH₃CH₂)₂AsH). Aluminum and gallium dopant sources may include alkylated and/or halogenated derivates, such as described with the empirical formula RₓMX₍₃₋ₓ₎, where M=Al or Ga, R=methyl, ethyl, propyl or butyl, X=Cl or F and x=0, 1, 2 or 3. Examples of aluminum and gallium dopant sources include trimethylaluminum (Me₃Al), triethylaluminum (Et₃Al), dimethylaluminumchloride (Me₂AlCl), aluminum chloride (AlCl₃), trimethylgallium (Me₃Ga), triethylgallium (Et₃Ga), dimethylgalliumchloride (Me₂GaCl) and gallium chloride (GaCl₃).

According to one or more embodiments, after the deposition process is terminated, the process chamber may be flushed with a purge gas or the carrier gas and/or the process chamber may be evacuated with a vacuum pump. The purging and/or evacuating processes remove excess deposition gas, reaction by-products and other contaminants. In an exemplary embodiment, the process chamber may be purged for about 10 seconds by flowing a carrier gas at about 80 slm. A cycle of deposition and etch may be repeated for numerous cycles.

In another aspect of the present invention, a blanket or non-selective deposition is performed at low temperatures, for example, below about 550° C. and lower, using a silicon source, preferably tetrasilane. This assists in amorphous growth (rather than polycrystalline) on dielectric surfaces such as oxide and nitride during the deposition step (nonselective deposition), which facilitates removal of the layer on dielectric surfaces by a subsequent etch step and minimizes damage on single crystalline layer grown on the crystalline substrate.

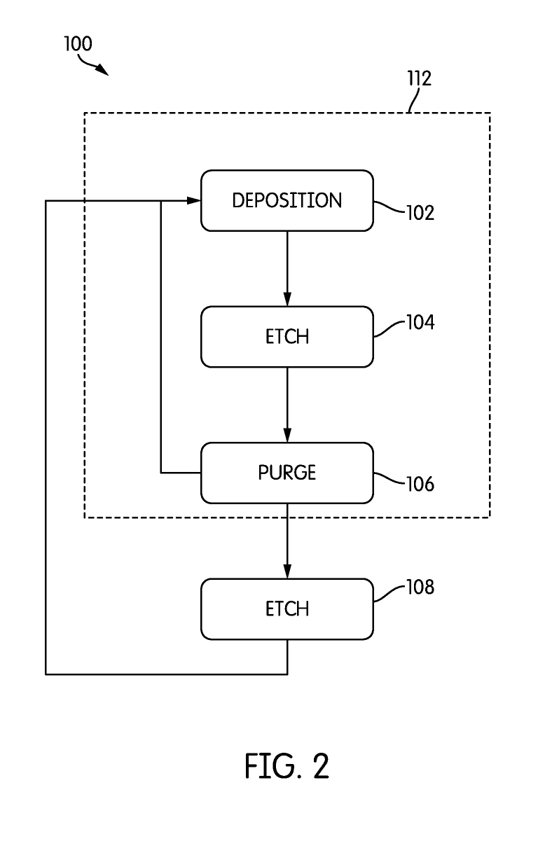

A typical selective epitaxy process 100 involves a deposition reaction and an etch reaction, shown schematically in FIG. 2 and described in Example 1 below. During the deposition process 102, the epitaxial layer is formed on a monocrystalline surface while a polycrystalline layer is deposited on at least a second layer, such as an existing polycrystalline layer and/or an amorphous layer. The deposition 102 and etch 104 reactions occur simultaneously with relatively different reaction rates to an epitaxial layer and to a polycrystalline layer. However, the deposited polycrystalline layer is generally etched at a faster rate than the epitaxial layer. Therefore, by changing the concentration of an etchant gas, the net selective process results in deposition of epitaxy material and limited, or no, deposition of polycrystalline material. For example, a selective epitaxy process may result in the formation of an epilayer of silicon-containing material on a monocrystalline silicon surface while no deposition is left on the spacer.

Typically growth on Si (100) is slightly faster than Si (110), even if CDE is used. Therefore, the epitaxial layer 302 is easily pinched off between Fin 304 to Fin 304′ creating a void or space 306 between the Fins 304 and 304′ and 304″, shown in FIG. 3A. As a result, the SEG has a strong faceted shape 300 (saw-tooth morphology) causing the performance of the device to degrade due to poor surface morphology providing contact formation. Using cyclical deposition etch (CDE) as described in detail in Example 1 below, epitaxial growth 302 is controlled as box like on both Si (100) and Si (110) surface of a three dimensional structure, such as but not limited to a FIN structure, 310 and 320 shown in FIGS. 3B and 3C, respectively. This is beneficial for conformal deposition and device performance is enhanced for contact resistance between source and drain and contact.

The epitaxial layer 310 on the FIN structure may be left un-merged 310 as shown in FIG. 3B or the epitaxial layer 310 may be left to grow and thereby merge as shown in FIG. 3C. In both cases, a space between Fin to Fin should be constant because parasitic capacitance is impacted to device performance. In order to merge perfectly, one approach is to use periodically etch out the pinched layer only by using a high pressure HCl etch 108 as shown in FIG. 2. The high pressure etch is accomplished by inserting a filter (not shown), such as, but not limited to a pico-trap, (as described in U.S. Pat. No. 7,134,506 and incorporated herein by reference) into the etch line that connects cylinder 204 with the Main Gas Cabinet as seen in FIG. 1. This approach is useful for either a merge or un-merge FIN device because the space between the fins is well controlled. Therefore, a CDE process using tetrasilane as described herein in combination with a periodically high pressure etch is useful to obtain conformal and uniform epi growth.

Embodiments of the present invention provide selective epitaxy processes for silicon-containing films, for example, Si:C films with high substitutional carbon concentration (greater than 1.8%), which can be used for forming tensile stressed channel of N-type Metal Oxide Semiconductor Field Effect Transistor (MOSFET) structure when epitaxial films are grown on recessed source/drain of a transistor. In general, it is difficult to achieve high substitutional carbon concentration (greater than 1.8%) in Si:C epitaxy. However, tetrasilane enables high growth rates at very low temperatures.

Further, SiGe grown epitaxially on the top of silicon has compressive stress inside the film because the lattice constant of SiGe is larger than that of silicon. The compressive stress is transferred in the lateral dimension to create compressive strain in the pMOS channel and to increase mobility of the holes. For nMOS application, SiC can be used in the recessed areas to create tensile stress in the channel, since the lattice constant of SiC is smaller than that of silicon. The tensile stress is transferred into the channel and increases the electron mobility. Therefore, in one embodiment, a first silicon-containing layer is formed with a first lattice strain value and a second silicon-containing layer is formed with a second lattice strain value.

To achieve enhanced electron mobility in the channel of nMOS transistors having a recessed source/drain using carbon-doped silicon epitaxy, it is desirable to selectively form the carbon-doped silicon epitaxial layer on the source/drain either through selective deposition or by post-deposition processing. Furthermore, it is desirable for the carbon-doped silicon epitaxial layer to contain substitutional C atoms to induce tensile strain in the channel. Higher channel tensile strain can be achieved with increased substitutional C content in a carbon-doped silicon source and drain. Achieving a 1.5% substitutional C is equivalent to approximately a 0.5% channel strain, whereas a 2% substitutional C is equivalent to approximately a 0.8% channel strain, whereas a 2.5% substitutional C is equivalent to approximately a 1.0% channel strain and a 3% substitutional C is equivalent to approximately a 1.2% channel strain.

Methods for formation of epitaxial layers containing n-doped silicon are known in the art and are not described in detail herein. Specific embodiments pertain to the formation and treatment of epitaxial layers in semiconductor devices, for example, MOSFET devices. In specific embodiments, the formation of the n-doped epitaxial layer involves exposing a substrate in a process chamber to deposition gases including a silicon source, a carbon source and an n-dopant source at a first temperature and pressure and then exposing the substrate to an etchant without varying the temperature or the pressure.

### EXAMPLES

The invention is further illustrated by the following non-limited examples. All scientific and technical terms have the meanings as understood by one with ordinary skill in the art. The specific examples which follow illustrate the techniques of the instant invention and are not to be construed as limiting the invention in sphere or scope. The methods and materials may be adapted to variation in order to produce the desired results embraced by this invention but not specifically disclosed.

As used herein “substrate” may be a support substrate with or without layers formed thereon. The support substrate may be an insulator or a semiconductor of a variety of doping concentrations and profiles and may, for example, be a semiconductor substrate of the type used in the manufacture of integrated circuits, the substrate may also be the interior wall of the chamber and can be made of any material, such as, but not limited to stainless steels, aluminum, glass, Si wafers, o-rings, etc.

### Example 1

### Tetrasilane CDE Net Growth Per Cycle Impact on FinFET Crystallographic Planes

As discussed previously, normal selective epitaxial growth (SEG) utilizing dichlorosilane chemistry (DSC) typically results in a saw-tooth morphology 300, as seen in FIG. 3A. It has been discovered that by controlling tetrasilane cycle deposition etch (CDE) net growth per cycle no defective layers is obtained for FinFET source/drain region and epitaxial doped-silicon growth on in. By using tetrasilane CDE, as disclosed herein, good morphology doped-silicon growth is achieved on the FIN and no facet formation under silicide layer is apparent. This ultimately has a benefit of reducing contact resistivity.

In order to reduce the net growth per cycle. (5-25 Å/cycle) there are two methods. First growth thickness may be reduced by deposition time or growth rate and second, increase etched thickness by etching time or etch rate. Both methods or a combination of the two are effective at reducing the net growth. As tested, the first method of reducing the thickness by reducing the growth rate or deposition time was more effective. However, the use of either method is dependent upon growth characteristics, due to plane, structure and so on.

After loading a substrate into the process chamber, the conditions in the process chamber are adjusted to a predetermined temperature and pressure. Both SOI or bulk Si with SiO₂ isolation are effective substrate. The Fins in this example are made with Si or SiGe or Ge. The process chamber is maintained at a temperature below about 550° C. during deposition and etching and was maintained at a pressure of about 10 Torr. The pressure may fluctuate during and between process steps, but is generally maintained constant.

During the deposition process the substrate is exposed to tetrasilane to form an epitaxial layer at a rate of about 20 sccm (0.11 g/min or 5-50 sccm) in combination with the dopant AsH₃ (1%) at a rate of about 90 sccm and diluted by the carrier gas H₂ introduced at the rate of 10 slm. While the dopant in this specific example is AsH₃ other dopants sources, such as boron, arsenic, phosphorus, gallium and/or aluminum may also be used. Deposition time was for 4.8 seconds and the growth was 27.5 Å.

The silicon sources as introduced to said chamber typically has a purity level in the range of approximately 95% to approximately 99.9% and having oxygenated impurities less than 2000 ppm and preferably having oxygenated impurities less than 2 ppm and more preferably having oxygenated impurities less than 500 ppb. The etching rate was performed for 15 seconds and the etch rate was 17.5 Å.

Following the deposition, an etching gas (HCl) is introduced at a rate of 500 sccm in addition to 10% GeH₄ at a rate of 150 sccm along with a hydrogen carrier gas at a rate of 2 slm. The chamber is then purged using HCl at a rate of 20 slm and H₂ at a rate of 80 slm for a period of 10 seconds in order to remove the Ge.

The net growth rate is 10 Å per cycle and the cycle number is determined by the desired thickness for the process. For example if the cycle number is 15 the total thickness of the fin in 150 Å. The end product results in a planar surface free of the saw-tooth morphology typically seen by standard (Dichlorosilane) DCS chemistry.

The epitaxial layer on the FIN structure may be left un-merged as seen in FIG. 3B or the epitaxial layer may be left to grow and thereby merge as shown in FIG. 3C. In order to merge perfectly, one approach is to use periodically etch out the pinched layer only by using a high pressure HCl etch 108 as shown in FIG. 2. The high pressure etch is accomplished by inserting a filter (not shown), such as, but not limited to a pico-trap, (as described in U.S. Pat. No. 7,134,506 and incorporated herein by reference) into the etch line that connects cylinder 204 with the Main Gas Cabinet as seen in FIG. 1. This approach is useful for either a merge or un-merge FIN device because the space between the fins is well controlled. Therefore, a CDE process using tetrasilane as described herein in combination with a periodically high pressure etch is useful to obtain conformal and uniform epi growth.

### Example 2

### Process for the Production of Highly Doped SiAs Epitaxy Layer

The present invention describes N-type doping with tetrasilane as Si precursor, eliminates the N type doping surface segregation, growth rate poisoning effect. Reducing these effects thus leads to same growth rates and doping concentrations on both 100 and 110 crystallographic planes. Cyclical deposition and etch (CDE) reduces defect level.

After loading a substrate into the process chamber, the conditions in the process chamber are adjusted to a predetermined temperature and pressure. In this particular example the process chamber is maintained at a temperature below about 550° C. during deposition and etching. The process chamber was maintained at a pressure of about 10 Torr. The pressure may fluctuate during and between process steps, but is generally maintained constant.

During the deposition process the substrate is exposed to a tetrasilane to form an epitaxial layer at a rate of about 20 sccm (0.11 g/min or 5-50 sccm) in combination with the dopant AsH₃ (1%) at a rate of about 300 sccm and diluted by the carrier gas H₂ introduced at the rate of 10 sccm. While the dopant in this specific example is AsH₃ other dopants sources, such as boron, arsenic, phosphorus, gallium and/or aluminum may also be used.

The silicon sources as introduced to said chamber typically has a purity level in the range of approximately 95% to approximately 99.9% and having oxygenated impurities less than 2000 ppm and preferably having oxygenated impurities less than 2 ppm and more preferably having oxygenated impurities less than 500 ppb.

Following the deposition an etching gas (HCl) is introduced at a rate of 500 sccm in addition to GeH4 (10%) at a rate of 150 sccm along with a hydrogen carrier gas at a rate of 2 slm. The chamber is then purged using HCl at a rate of 20 slm and H₂ at a rate of 80 slm. This process is cycled 20 times to produce the final product as described in Table 1.

TABLE 1

| Substrate | As (atoms/cm³) | Thickness (nm) | Net Growth (Å) |
|---|---|---|---|
| 100 | 4.7E+20 | ~23 | ~11 |
| 110 | 5.1E+20 | ~18 | ~9 |

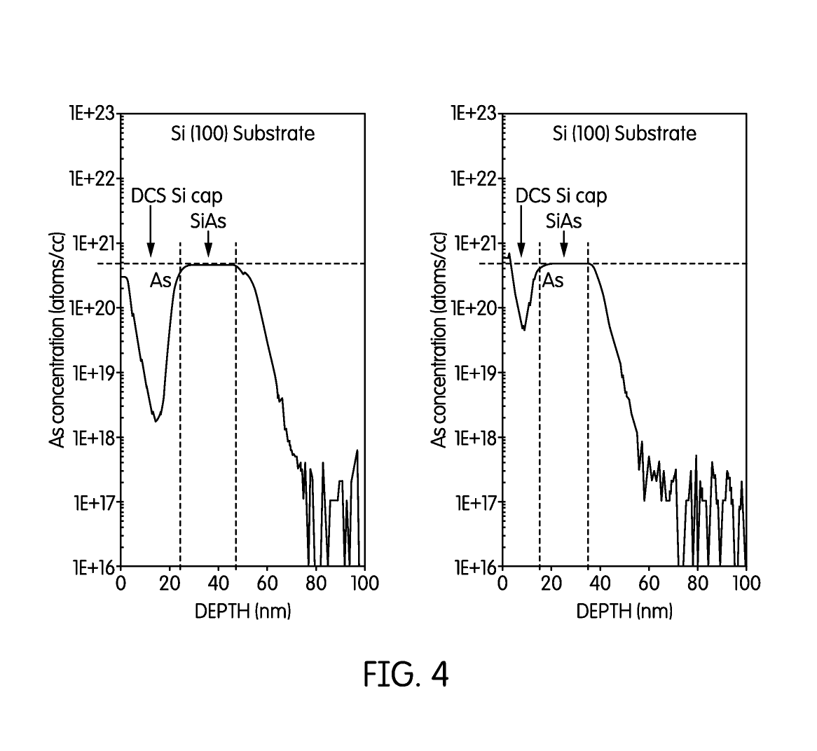

For the nFET n-type doping with tetrasilane incorporates 4E20-1E21 Phos/As doping. Subsequent implants are not necessarily required. Maximum electrically active doping is as high as 4E+20 atoms/cm³ for As. Strain with C is an option as defect levels are manageable. Same growth rates and dopant concentrations are achieved on Si (100) and Si (110) crystallographic plane, see FIG. 4.

For pFET, B doping with tetrasilane incorporates up to 1E+21 atoms/cm³ B. Can be obtained with good crystalline quality and morphology. Subsequent implants are not required. Strain with SiGe is an option as defect levels are low. But if needed, SiB can be growth to similar concentrations as with SiGe with no deleterious effects. Same growth rates and dopant concentrations obtained on Si (100) no 110 crystallographic plane.

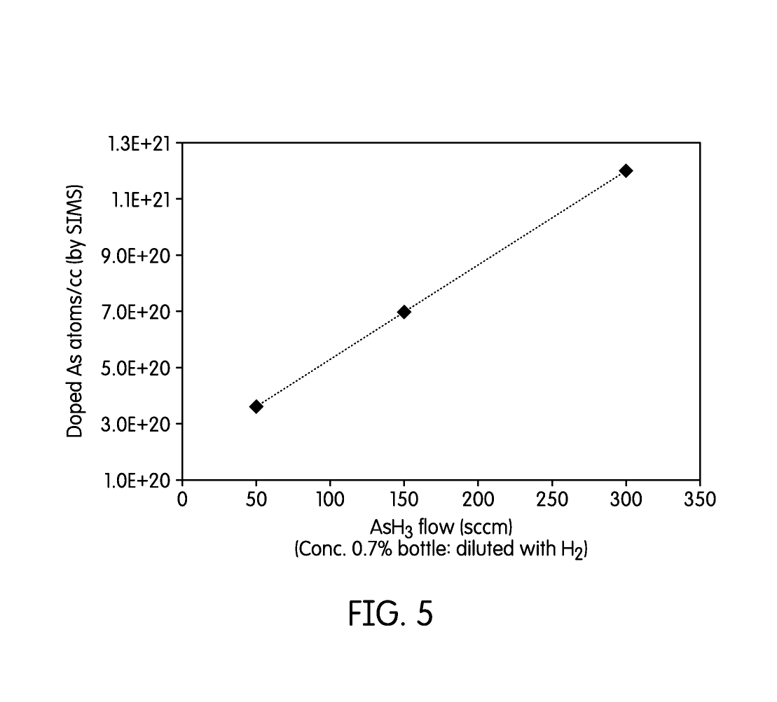

Post nFET Epi: For contact, SiAs/SiP Epi with tetrasilane can incorporate an extremely high dopant level of 1E+21 atoms/cm³ total As/P as shown in FIG. 5. This SiAs/SiP Epi results in no crystal damage, uniform dopant profile and no thermal cycle.

### Example 3

### Obtaining Selectivity and Uniform Fin Merge with CDE

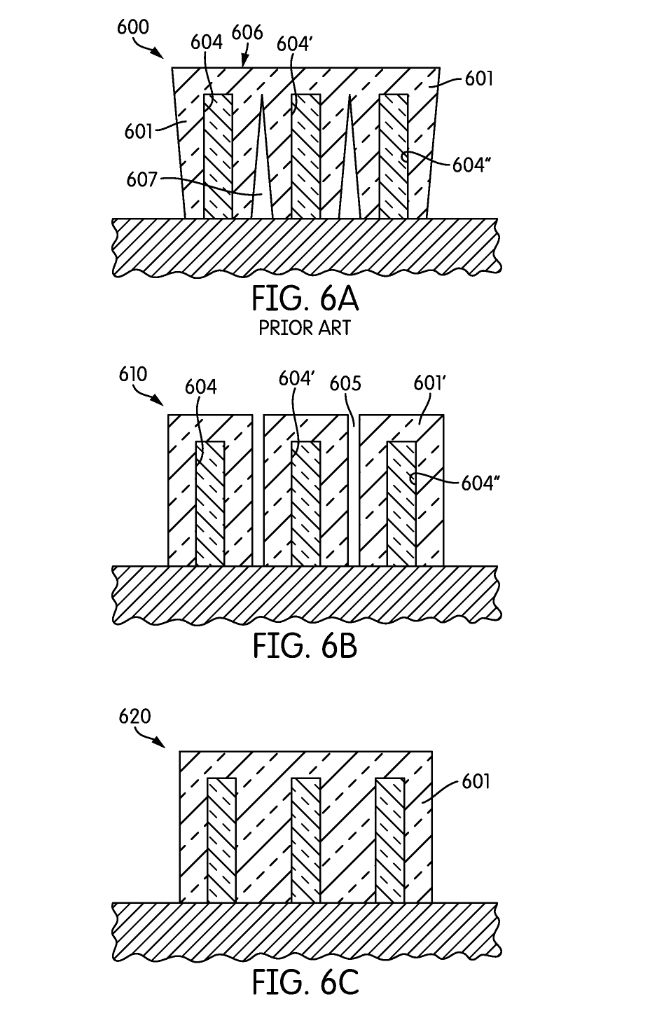

As discussed previously, the fabrication of uniform, ultra thin fins is one of the key challenges in FinFET fabrication. Due to non-ideal anisotropic over etch, the epitaxial layer 601 deposited on the fins 604, 604′ and 604″ can end up having a slightly triangular shape whereby voids 607 are created especially at the bottom of the Fins. Once the facets merge at the top 606, the reactant gases cannot reach the bottom of the Fin resulting in voids 607, see FIG. 6A. Concave and convex surfaces can also end up during typical fabrication processes.

In an embodiment, according to the present invention a uniform Fin merge 610 is achieved during the higher silane CDE process by etching back the Fins 602 at certain intervals during the CDE process thereby selectively targeting the top of the epi growth 602′ thus keeping a space 605 between the fins 604, 604′ and 604″ open so a bottom up fill can occur, see FIG. 6B. This etch back is a different etch chemistry than that used for etchant in the standard CDE process and is discussed in further detail below.

This etch is also instrumental in obtaining selective films. The high As/P doping is problematic for obtaining selective films. The higher the doping the more difficult to obtain selectivity on the non Si area. As doping is more difficult than Phos doping in regard to the selectivity.

The process initially starts out as described in Example 1 and process 100 shown in FIG. 2. After process 112 has cycled the predetermined number of time (1-5 cycles) an etch back occurs. This etch back step 108 requires HCl purified to approximately 10 ppb via a filter (not shown) such as a pico-trap, as described in U.S. Pat. No. 7,314,506 and incorporated herein by reference, to reduce moisture related defects and it is used at high pressure. As discussed previously the filter is positioned in the line connecting cylinder 208 with the main Gas Cabinet. The combination of high HCl partial pressures and high total pressure in the CVD “viscous flow” regime allows for selectively etching the top of the on the Fin epi growth 602′ vs the bottom of the Fin growth, resulting in a uniform space 605 between the Fins 604, 604′ and 604″ (FIG. 6B) which can be grown until the device 620 wherein the epi layers merge (FIG. 6C) without any presence of a void 605.

### Example 4

### Fin Merge in n-Type FinFET SiGeP/SiGeAs

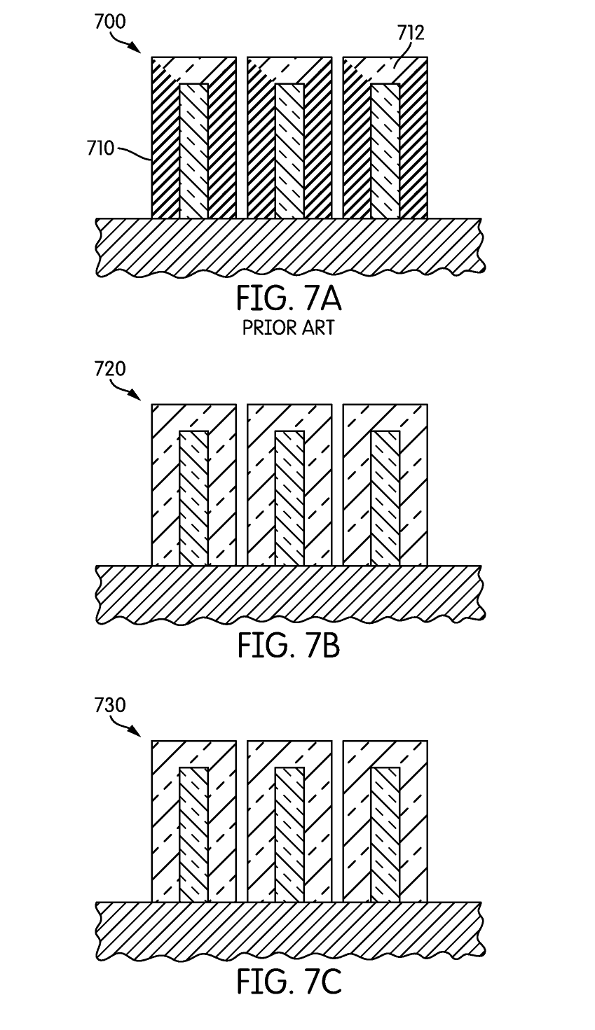

The present embodiment pertains to n type FinFET. Historically, FinFET merge is accomplished using SiP/SiCP; however, the epitaxial layer 710 on the sidewall Si(110) is defective having a crystalline structure which is susceptible to degradation while the Si (100) layer 712 is normal as shown in FIG. 7A.

Utilize n-doped SiGe for Fin merge instead of SiP/SiCP. TCAD simulation have shown there is almost no strain to be achieved in channel for 14 nm geometries for either SiGeB(pFET) or SiCP(nFET). Therefore, addition of Ge % to SiP for nFET should not be a significant performance detriment. If some residual strain is generated in n-FinFET due to use of SiGe that is deleterious, C may be used to compensate the compressive strain.

SiGe growth has been shown to be defect free on 110 plane of Fin. SiGe growth has also demonstrated planar epi surface for silicidation on FinFET. Adopting SiGe for nFET will allow same growth characteristics as demonstrated for pFET. Either As or P can be used as n-type dopant.

Enabling Technology for higher order silanes: N type doping is problematic in Si/SiGe with DCS and lower silanes. Tetrasilane allows very high N type doping of either Si/SiGe films with no reduction in growth rate.

Following the procedures of Example 1, the FinFET 720 shown in FIG. 7B was fabricated, wherein:

SiGeAs (10 Torr, 500° C. 1 step).
Resulting in approximately 10-50% and preferably approximately 20-30% SiGe,
As-4E+20 atoms/cm³: AsH₃ (0.1% diluted)=15 sccm.

### Thickness 20 nm.

tetrasilane 29 mg/minute for 123 seconds.

Following the procedures of Example 1, the FinFET 730 shown in FIG. 7C was fabricated, wherein:

SiGeP (10 Torr, 500° C. 1 step)
Resulting in approximately 10-50% and preferably approximately 20-40% SiGe, P-4E+20 atoms/cm³: PH₃ (10% diluted)=9 sccm

### Thickness 20 nm

tetrasilane 29 mg/minute for 197 seconds.

Adoption of n type doped SiGe is capable of solving some of the major issues in the existing technology, such as:
eliminate dislocations on 110
Allow smooth morphology on Epi top surface for silicidation
In combination with tetrasilane, high doping can be achieved. No subsequent implants needed.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments. The order of description of the above method should not be considered limiting, and methods may use the described operations out of order or with omissions or additions.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

The foregoing description is considered as illustrative only of the principles of the invention. Further, since numerous modifications and changes will readily occur to those skilled in the art, it is not desired to limit the invention to the exact construction and process as described above. Accordingly, all suitable modifications and equivalents may be resorted to falling within the scope of the invention as defined by the claims that follow. The words “comprise,” “comprising,” “include,” “including,” and “includes” when used in this specification and in the following claims are intended to specify the presence of stated features, integers, components, or steps, but they do not preclude the presence or addition of one or more other features, integers, components, steps, or groups thereof

What is claimed is:

1. A method for forming an epitaxial film on a three-dimensional structure in a chemical vapor deposition system, comprising:
providing a three-dimensional structure disposed within a chamber;
introducing a silicon precursor to said chamber at a temperature of less than 600° C., wherein said silicon precursor is accompanied with a carrier gas wherein said carrier gas has a flow rate of 10 to 200 times greater than the flow rate of said silicon precursor; and
forming an epitaxial film comprising multiple epilayers by way of a cyclical deposition and etch process wherein each epilayer is formed as a result of (i) exposing said three-dimensional structure to a process gas containing said silicon precursor to deposit a silicon-containing epilayer across the surfaces of said three-dimensional structure wherein said process carrier gas flows at a rate of about 100 to 2000 times greater than said silicon precursor and (ii) exposing said deposited silicon layer to an etchant gas so that the net growth of each epilayer is no great than 5-25 Å per cycle.

2. The method of claim 1, wherein said three-dimensional structure is a FinFET device.

3. The method of claim 1, further comprising introducing a carbon precursor in combination with said silicon precursor.

4. The method of claim 1, further comprising introducing a germane precursor in combination with said silicon precursor.

5. The method of claim 3, further comprising introducing a germane precursor in combination with said silicon precursor.

6. The method of claim 1, wherein the germane precursor is selected from the group consisting of GeH₄ and Ge₂H₆.

7. The method of claim 1, wherein said silicon precursor is tetrasilane.

8. The method of claim 1, wherein said silicon precursor is a combination of one or more of the following: n-tetrasilane, iso-tetrasilane, and/or cyclo-tetrasilane.

9. The method of claim 7, wherein said tetrasilane introduced to said chamber has a purity level in the range of approximately 95% to 99.9%.

10. The method of claim 7, wherein said tetrasilane introduced to said chamber has oxygenated impurities of less than 2000 ppm.

11. The method of claim 1, wherein said carbon precursor as introduced to said chamber has a purity level in the range of approximately 97% to approximately 99.9%.

12. The method of claim 1, wherein said a carbon precursor as introduced to said chamber has oxygenated impurities of less than 100 ppm.

13. The method of claim 3, wherein the carbon precursor is selected from the group consisting of tetramethyldisilane (TMDS), monosilylmethane, disilylmethane, trisilylmethane, tetrasilylmethane, monomethyl silane, dimethyl silane and 1,3-disilabutane, monomethyl silane (MMS), dimethyl silane, methylsilane, dimethylsilane, ethylsilane, methane, ethylene, ethyne, propane, propene, butyne, dodecamethylcyclohexasilane, and tetramethyldisilane.

14. The method of claim 3, wherein the carbon precursor comprises a formula SiₓH_{y}(CH₃)_{z}, where x is an integer in the range of 1 to 6 and where y and z are each an independently integer in the range of 0 to 6.

15. The method of claim 1, wherein said chamber has a temperature in the range of about 250° C. to about 600° C.

16. The method of claim 1, wherein said chamber has a pressure of about 100 milliTorr to about 10 Torr.

17. The method of claim 1, wherein a dopant is introduced into the chamber in combination with said silicon precursor.

18. The method of claim 17, wherein said dopant is selected from the group consisting of AsH₃, PH₃, B₂H₆, boron, arsenic, phosphorous, gallium and aluminum.

19. The method of claim 16, wherein said epitaxial film contains a dopant in the range of 1E+20 atoms/cm³-5E+21 atoms/cm³.

20. The method of claim 2, wherein said epilayers are periodically exposed to an HCl etching gas purified to about 10 ppb under a pressure in the range of 100-700 Torr wherein said FinFET device comprises two or more fins have vertical surface wherein said epilayers forming on the vertical surface of said fins remain vertical.

21. The method of claim 20, wherein the growth of said epilayers is stopped leaving a space between each Fin.

22. The method of claim 20, wherein the growth of said epilayers continues until said epilayers merge into one contiguous epitaxial layer.

23. A method for forming an epitaxial film on a FinFET device in a chemical vapor deposition system, comprising:
providing the FinFET device disposed within a chamber;
introducing a silicon precursor to said chamber at a temperature of less than 600° C., wherein said silicon precursor is accompanied with a carrier gas wherein said carrier gas has a flow rate of 10 to 200 times greater than the flow rate of said a silicon precursor;
forming an epitaxial film comprising multiple epilayers by way of a cyclical deposition and etch process wherein each epilayer is formed as a result of (i) exposing said FinFET device to a process gas containing said silicon precursor to deposit a silicon-containing epilayer across the surfaces of the FinFET device wherein said process carrier gas flows at a rate of about 100 to 2000 times greater than said silicon precursor and (ii) exposing said deposited silicon layer to an etchant gas so that the net growth of each epilayer is no great than 5-25 Å per cycle; and
exposing the epitaxial layers periodically to an HCl etching gas purified to about 10 ppb under a pressure in the range of 100-700 Torr wherein said FinFET device comprises two or more fins have vertical surface wherein said epilayers forming on the vertical surface of the fins remain vertical.

24. A method for forming an epitaxial film on a FinFET device in a chemical vapor deposition system, comprising:
providing the FinFET device disposed within a chamber;
introducing tetrasilane to said chamber at a temperature of less than 600° C., wherein said tetrasilane is accompanied with a carrier gas wherein said carrier gas has a flow rate of 10 to 200 times greater than the flow rate of said tetrasilane;
forming an epitaxial film comprising multiple epilayers by way of a cyclical deposition and etch process wherein each epilayer is formed as a result of (i) exposing said FinFET device to a process gas containing said silicon precursor to deposit a silicon-containing epilayer across the surfaces of the FinFET device wherein said process carrier gas flows at a rate of about 100 to 2000 times greater than said tetrasilane and (ii) exposing said deposited tetrasilane layer to an etchant gas so that the net growth of each epilayer is no great than 5-25 Å per cycle; and
exposing the epitaxial layers periodically to an HCl etching gas purified to about 10 ppb under a pressure in the range of 100-700 Torr wherein said FinFET device comprises two or more fins have vertical surface wherein said epilayers forming on the vertical surface of the fins remain vertical.
